(19) United States
(12) Patent Application Publication
(10) Pub. No.: US 2025/0098542 A1
(43) Pub. Date: Mar. 20, 2025

(54) PIEZOELECTRIC LAMINATE AND PIEZOELECTRIC ELEMENT

(71) Applicant: FUJIFILM CORPORATION, Tokyo (JP)

(72) Inventors: Hiroyuki KOBAYASHI, Kanagawa (JP); Seigo NAKAMURA, Kanagawa (JP)

(21) Appl. No.: 18/805,550

(22) Filed: Aug. 15, 2024

(30) Foreign Application Priority Data
Sep. 14, 2023 (JP) 2023-149247

(51) Int. Cl. H10N 30/00; C04B 35/01; C04B 41/45; C04B 41/50; C04B 41/87; H10N 30/853

(52) U.S. Cl. CPC H10N 30/708; C04B 35/01; C04B 41/4529; C04B 41/5041; C04B 41/5042; C04B 41/87; H10N 30/8554; C04B 2235/3289; C04B 2235/768; C04B 2235/781

(57) ABSTRACT

A piezoelectric laminate comprise: a substrate; and a lower electrode layer, a seed layer, and a piezoelectric film, in which the piezoelectric film contains, as a main component, a first perovskite-type oxide containing Pb, Zr, Ti, and Nb, the seed layer contains, as a main component, a second perovskite-type oxide that is lattice-matched with the first perovskite-type oxide, and in a crystal grain size distribution acquired by an electron back scattered diffraction method, a proportion of crystal grains having a grain size of 100 nm or less is 15% or less in the piezoelectric film, and, the piezoelectric film satisfies the following expressions: |Ec⁺+Ec⁻ |<|Ec⁺−Ec⁻|, 55 kV/cm≤Ec⁺≤75 kV/cm, and 75 kV/cm≤Ec⁺−Ec⁻≤100 kV/cm, wherein Ec⁺ is a positive-side coercive electric field and Ec⁻ is a negative-side coercive electric field in polarization-electric field characteristics.

### CROSS REFERENCE TO RELATED APPLICATIONS

This application claims priority from Japanese Application No. 2023-149247, filed on Sep. 14, 2023, the entire disclosure of which is incorporated herein by reference.

### BACKGROUND

### 1. Technical Field

The present disclosure relates to a piezoelectric laminate and a piezoelectric element.

### 2. Related Art

As a material having excellent piezoelectric characteristics and excellent ferroelectricity, there is known a perovskite-type oxide such as lead zirconate titanate (Pb(Zr,Ti)O₃, hereinafter referred to as PZT). A piezoelectric body consisting of a perovskite-type oxide is applied as a piezoelectric film in a piezoelectric element comprising a lower electrode, a piezoelectric film, and an upper electrode on a substrate. This piezoelectric element has been developed into various devices such as a memory, an inkjet head (an actuator), a micromirror device, an angular velocity sensor, a gyro sensor, a piezoelectric micromachined ultrasonic transducer (PMUT), and an oscillation power generation device.

JP2009-71295A, JP2014-60330A, and the like disclose that in a PZT-based perovskite-type oxide, a piezoelectric film having high aligning properties and good piezoelectric performance can be realized by adding niobium (Nb) to a B site. WO2015/146607A discloses that piezoelectric performance of a piezoelectric film produced by a sol-gel method can be improved by adding manganese (Mn) in addition to Nb.

JP2009-71295A discloses that in a piezoelectric film consisting of Nb-added PZT, grain sizes of crystal grains are widely distributed, and crystals having large grain sizes and crystals having small grain sizes are mixed, so that the piezoelectric performance can be improved. Specifically, it is disclosed that crystal grains having a grain size of 100 nm or less are preferably 20% or more and crystal grains having a grain size of 500 nm or more are preferably 5% or more.

### SUMMARY

Meanwhile, in order to improve piezoelectric performance, it is known to provide a seed layer between a piezoelectric film and a lower electrode. However, in JP2009-71295A, sufficient studies have not been made on a case where the seed layer is provided.

The technique of the present disclosure has been made in view of the above circumstances, and an object of the present disclosure is to provide a piezoelectric laminate and a piezoelectric element, which have high piezoelectric performance and higher reliability than that in the related art, in a case where a seed layer is provided.

The present disclosure relates to a piezoelectric laminate comprising: a substrate; and a lower electrode layer, a seed layer, and a piezoelectric film provided in this order on the substrate, in which the piezoelectric film contains, as a main component, a first perovskite-type oxide containing Pb, Zr, Ti, and Nb, the seed layer contains, as a main component, a second perovskite-type oxide that is lattice-matched with the first perovskite-type oxide, and in a crystal grain size distribution acquired by an electron back scattered diffraction method, a proportion of crystal grains having a grain size of 100 nm or less is 15% or less in the piezoelectric film, and in a case where a positive-side coercive electric field is defined as Ec⁺ and a negative-side coercive electric field is defined as Ec⁻ in polarization-electric field characteristics, the piezoelectric film satisfies the following expressions: |Ec⁺+Ec⁻|<|Ec⁺−Ec⁻|, 55 kV/cm≤Ec⁺≤75 kV/cm, and 75 kV/cm≤Ec⁺−Ec⁻≤100 kV/cm.

It is preferable that the piezoelectric film is a sputtered film.

It is preferable that the proportion of the crystal grains having a grain size of 100 nm or less is 10% or less.

It is preferable that the first perovskite-type oxide is represented by Pbₐ{(ZrₓTi₁₋ₓ)_{1-y}Nb_{y}}O₃, where 0<x<1, 0.08≤y≤0.15, and 0.9≤a≤1.2 are satisfied.

It is preferable that the seed layer has conductivity.

It is preferable that the second perovskite-type oxide has a lattice constant of 0.39 nm to 0.405 nm in a case of being regarded as a pseudo-cubic crystal.

It is preferable that the second perovskite-type oxide is SrRuO₃ or BaRuO₃.

The present disclosure relates to a piezoelectric element comprising: the piezoelectric laminate according to the present disclosure; and an upper electrode layer provided on the piezoelectric film of the piezoelectric laminate.

According to the technology of the present disclosure, it is possible to provide a piezoelectric laminate and a piezoelectric element having high piezoelectric performance and higher reliability than that in the related art.

### BRIEF DESCRIPTION OF THE DRAWINGS

FIG. 1 is a schematic cross-sectional view showing a layer configuration of a piezoelectric laminate and a piezoelectric element of an embodiment.

FIG. 2 is a schematic view of a P-E hysteresis curve showing polarization-electric field (P-E) characteristics of the piezoelectric element of the embodiment.

FIG. 3 shows P-E hysteresis curves of Example 1 and Comparative Example 1.

FIG. 4 is an image pattern of crystal grains on a surface of a piezoelectric film of Example 1 acquired by an EBSD method.

FIG. 5 is a grain size distribution in the piezoelectric film of Example 1 acquired by the EBSD method.

### DESCRIPTION OF EMBODIMENTS

Hereinafter, an embodiment according to the present disclosure will be described with reference to the drawings. In the drawings below, a layer thickness of each of layers and a ratio thereof are appropriately changed and drawn for easy visibility, and thus they do not necessarily reflect the actual layer thickness and ratio. In the present specification, a numerical range expressed using “to” means a range that includes preceding and succeeding numerical values of “to” as a lower limit value and an upper limit value, respectively. In numerical ranges that are described stepwise in the present disclosure, an upper limit value or a lower limit value described in a certain numerical range may be replaced with an upper limit value or a lower limit value of another numerical range described stepwise. In addition, in the numerical ranges described in the present disclosure, an upper limit value or a lower limit value described in a certain numerical range may be replaced with values shown in Examples.

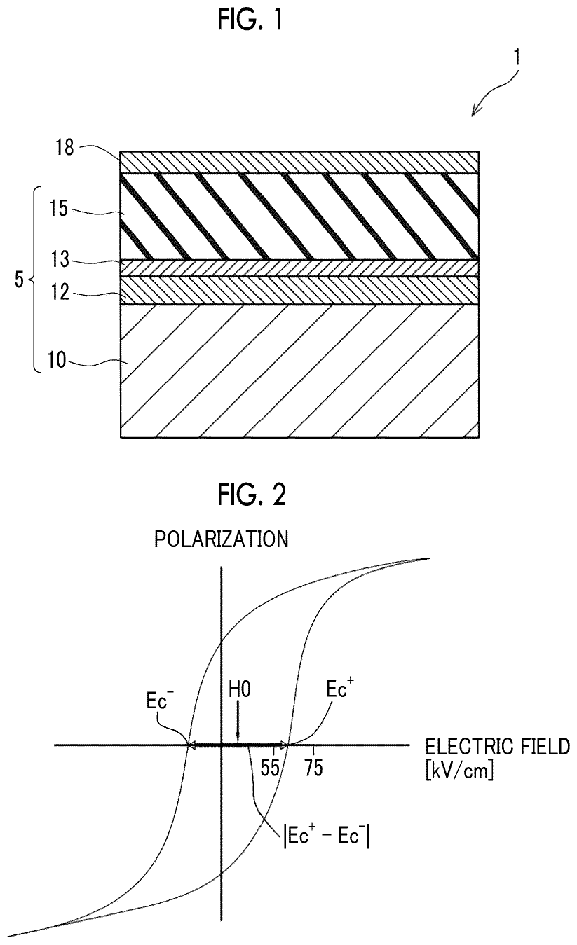

FIG. 1 is a schematic cross-sectional view showing a layer configuration of a piezoelectric laminate 5 and a piezoelectric element 1 having the piezoelectric laminate 5, according to an embodiment. As shown in FIG. 1, the piezoelectric element 1 has the piezoelectric laminate 5 and an upper electrode layer 18. The piezoelectric laminate 5 has a substrate 10; and a lower electrode layer 12, a seed layer 13, and a piezoelectric film 15 which are laminated in order on the substrate 10. Here, “lower” and “upper” do not respectively mean top and bottom in a vertical direction. An electrode disposed on the substrate 10 side with the piezoelectric film 15 being interposed is merely referred to as the lower electrode layer 12, and an electrode disposed on a side opposite to the substrate 10 with respect to the piezoelectric film 15 is merely referred to as the upper electrode layer 18.

The substrate 10 is not particularly limited, and examples thereof include silicon, glass, stainless steel, yttrium-stabilized zirconia, alumina, sapphire, silicon carbide, or other substrates. As the substrate 10, a laminated substrate such as a thermal oxide film-attached silicon substrate having a SiO₂ oxide film formed on a surface of a silicon substrate may be used. Further, as the substrate 10, a resin substrate such as polyethylene terephthalate (PET), polyethylene naphthalate (PEN), polyimide, and the like may be used.

The lower electrode layer 12 is paired with the upper electrode layer 18 and is an electrode for applying a voltage to the piezoelectric film 15. The main component of the lower electrode layer 12 is not particularly limited, and examples thereof include metals such as gold (Au), platinum (Pt), iridium (Ir), ruthenium (Ru), titanium (Ti), molybdenum (Mo), tantalum (Ta), and aluminum (Al) or metal oxides thereof, and combinations thereof. In addition, indium tin oxide (ITO) or the like may be used. The lower electrode layer 12 may be a single layer or may have a laminated structure consisting of a plurality of layers. In a case where the lower electrode layer 12 has a laminated structure, it is also preferable to have a configuration in which an adhesion layer such as Ti, TiW, or ZrO₂ is provided on the substrate 10 side in addition to a conductive layer consisting of the above-described material.

A layer thickness of the lower electrode layer 12 is not particularly limited, and is preferably about 50 nm to 300 nm and more preferably 100 nm to 300 nm as a whole.

The upper electrode layer 18 is paired with the lower electrode layer 12 and is an electrode for applying a voltage to the piezoelectric film 15. The main component of the upper electrode layer 18 is not particularly limited, and examples thereof include metals such as Au, Pt, Ir, Ru, Ti, Mo, Ta, and Al or metal oxides thereof, and combinations thereof. In addition, indium tin oxide (ITO), LaNiO₃, SrRuO₃, or the like may be used. The upper electrode layer 18 may be a single layer or may have a laminated structure consisting of a plurality of layers. It is noted that from the viewpoint of further suppressing oxygen diffusion from the piezoelectric film 15, at least a region of the upper electrode layer 18 which is in contact with the piezoelectric film 15 is preferably an oxide electrode.

A layer thickness of the upper electrode layer 18 is not particularly limited, and is preferably about 50 nm to 300 nm and more preferably 100 nm to 300 nm.

The piezoelectric film 15 contains a first perovskite-type oxide containing Pb, Zr, Ti, and Nb as a main component. In the present specification, the main component refers to a component occupying 80 mol % or more. It is preferable that 90 mol % or more of the piezoelectric film 15 is occupied by the first perovskite-type oxide, and it is more preferable that 100 mol % of the piezoelectric film 15 is occupied by the first perovskite-type oxide (however, containing unavoidable impurities).

Nb-added PZT which is a first perovskite-type oxide containing Pb, Zr, Ti, and Nb is represented by the following general formula.

Pbₐ{(ZrₓTi₁₋ₓ)_{1-y}Nb_{y}}O₃
Here, it is preferable that 0<x<1, 0<y<1, and 0.9≤a≤1.2, and it is more preferable that 0.08≤y≤0.15.

In a case where the piezoelectric film 15 is formed as a film of a sputtered film formed by a vapor-phase growth method such as sputtering, it is possible to obtain a piezoelectric film having a very high piezoelectric constant.

It is said that, in the PZT-based perovskite-type oxide, high piezoelectric characteristics are exhibited at a morphotropic phase boundary (MPB) and its vicinity. Zr:Ti (molar ratio) of around 52/48 is an MPB composition, and in the above general formula, the MPB composition or its vicinity is preferable. The “MPB or its vicinity” refers to a region in which a phase transition occurs in a case where an electric field is applied to the piezoelectric film. Specifically, Zr:Ti (molar ratio) is preferably in a range of 45:55 to 55:45, that is, in a range of x=0.45 to 0.55.

A film thickness of the piezoelectric film 15 is preferably 0.2 μm or more and 5 μm or less, and more preferably 1 μm or more.

In a crystal grain size distribution acquired by an electron back scattered diffraction (EBSD) method, a proportion of crystal grains having a grain size of 100 nm or less is 15% or less in the piezoelectric film 15. It is preferable that the proportion of the crystal grains having a grain size of 100 nm or less is 10% or less. It is preferable that an average grain size is 200 nm or more, and it is more preferable that the average grain size is 500 nm or more.

The seed layer 13 contains, as a main component, a second perovskite-type oxide that is lattice-matched with the first perovskite-type oxide. The second perovskite-type oxide is a perovskite-type oxide having a composition different from that of the first perovskite-type oxide.

By providing the seed layer 13, crystallinity of the piezoelectric film 15 to be formed on an upper layer can be improved. The piezoelectric film 15 formed on the seed layer 13 may be an epitaxial film that is epitaxially grown.

The second perovskite-type oxide preferably has a lattice constant of 0.39 nm to 0.405 nm in a case of being regarded as a pseudo-cubic crystal. In a case where the lattice constant is in this range, since the second perovskite-type oxide is lattice-matched with the first perovskite-type oxide which is Nb-added PZT, the crystallinity of the piezoelectric film 15 formed on the upper layer can be improved.

It is preferable that the seed layer 13 has conductivity. It should be noted that having conductivity means having electrical resistivity sufficient to function as an electrode. Here, it is regarded as having conductivity in a case where the electrical resistivity at 20° C. is 10⁻⁵ Ω·m or less. In a case where the seed layer 13 has conductivity, the seed layer 13 can function as an electrode for applying a driving voltage to the piezoelectric film 15 together with the lower electrode layer 12.

Specific examples of the second perovskite-type oxide include SrRuO₃, BaRuO₃, and PbTiO₃. The above oxides illustrated as the second perovskite-type oxide have a lattice constant of 0.39 nm to 0.405 nm in a case of being regarded as a pseudo-cubic crystal. As the second perovskite-type oxide, SrRuO₃ or BaRuO₃ having high conductivity is particularly preferable.

FIG. 2 is a schematic view of a P-E hysteresis curve showing polarization-electric field (P-E) characteristics acquired by grounding the lower electrode layer 12 and applying a sweep voltage to the piezoelectric film 15 using the upper electrode layer 18 as a drive electrode. In the P-E hysteresis curve, a case where a positive potential is applied to the upper electrode layer 18 is shown as a positive voltage, and a case where a negative potential is applied to the upper electrode layer 18 is shown as a negative voltage. Since a first cycle of the measurement is affected by a polarization state before the measurement, data may be unstable. However, generally, a curve that stably exhibits substantially the same behavior is obtained from a second cycle of the measurement. In an evaluation of a coercive electric field of the piezoelectric film, a stable P-E hysteresis curve is used. For example, data of a third cycle is used.

As shown in FIG. 2, in a case where a positive-side coercive electric field is defined as Ec⁺ and a negative-side coercive electric field is defined as Ec⁻, the piezoelectric film 15 satisfies the following expressions:

$$\vert {Ec}^{+} + {Ec}^{-} \vert < \vert {Ec}^{+} - {Ec}^{-} \vert ,$$

$$55 kV / cm \leq {Ec}^{+} \leq 75 kV / cm , and$$

$$75 kV / cm \leq {Ec}^{+} - {Ec}^{-} \leq 100 kV / cm .$$

The coercive electric field is an electric field at which the polarization is zero in the P-E hysteresis curve, and as shown in FIG. 2, there are two coercive electric fields in one hysteresis curve. The positive-side coercive electric field Ec⁺ refers to a coercive electric field on a relatively positive electric field side (right side in the drawing) between the two coercive electric fields, and the negative-side coercive electric field Ec⁻ refers to a coercive electric field on a relatively negative electric field side (left side in the drawing).

In the P-E hysteresis curve shown in FIG. 2, an absolute value of a difference Ec⁺−Ec⁻ between the coercive electric fields is a width of a hysteresis. Half (Ec⁺+Ec⁻)/2 of a sum of the coercive electric fields indicates a center H0 of the hysteresis. A shift of the center H0 of the hysteresis from an origin indicates that the piezoelectric film 15 has a spontaneous polarization. In addition, the shift of the center H0 of the hysteresis to the positive electric field side indicates that the spontaneous polarization is generated in a direction opposite to a direction of the electric field in a case where a positive voltage is applied.

|Ec⁺−Ec⁻| is the absolute value of the difference between the coercive electric fields and indicates the width of the hysteresis curve as described above. In addition, as described above, the center of the hysteresis curve is represented by (Ec⁺+Ec⁻)/2. Accordingly, the absolute value of (Ec⁺+Ec⁻)/2 indicates a shift amount of the hysteresis curve.

The above-described Relational Expression of |Ec⁺+Ec⁻|<|Ec⁺−Ec⁻| has the same meaning as |Ec⁺+Ec⁻|/2<|Ec⁺−Ec⁻|/2, and means that the shift amount of the hysteresis curve is less than half of the hysteresis width, that is, the hysteresis curve includes the origin.

In general, the spontaneous polarization of the Nb-added PZT is directed upward in a film thickness direction from a substrate side immediately after film formation. Therefore, generally, a piezoelectric device provided with the Nb-added PZT film is driven in a state in which a direction of the spontaneous polarization of the Nb-added PZT film is matched with a direction of the electric field. Therefore, in the piezoelectric device provided with the Nb-added PZT film in the related art, the upper electrode layer 18 is generally used as a drive electrode to perform negative voltage driving. However, in the piezoelectric film 15 of the present embodiment as the Nb-added PZT film, as described above, the hysteresis curve includes the origin and the width of the hysteresis curve is large. This means that the polarization can be made in a direction opposite to the direction of spontaneous polarization immediately after film formation. In a case where the upper electrode layer 18 is used as a drive electrode, positive voltage driving can be performed by making the polarization in a direction opposite to the direction of spontaneous polarization immediately after film formation. A driving drive for positive voltage driving is cheaper than a driving drive for negative voltage driving, which leads to a reduction in cost of the piezoelectric device.

As described above, the piezoelectric laminate 5 and the piezoelectric element 1 of the present embodiment include the seed layer 13 containing the second perovskite-type oxide as a main component between the piezoelectric film 15 containing the first perovskite-type oxide containing Pb, Zr, Ti, and Nb as a main component and the lower electrode layer 12, and the piezoelectric film 15 has a proportion of crystal grains having a crystal grain size of 100 nm or less acquired by an electron back scattered diffraction method of 15% or less. In addition, the piezoelectric film 15 satisfies the above-described relationship in a case where the positive-side coercive electric field is Ec⁺ and the negative-side coercive electric field is Ec⁻ in polarization-electric field characteristics.

The present inventors have found that piezoelectric performance and reliability of the piezoelectric film can be improved by the above-described configuration (see Examples described later).

As described above, |Ec⁺−Ec⁻| corresponds to the width of the hysteresis. The larger the hysteresis width is, the more stable the piezoelectric film is, in which polarization reversal is less likely to occur. Meanwhile, in a case where |Ec⁺−Ec⁻| is too large, it is difficult to align the polarization, and thus the piezoelectric performance deteriorates in a case where the polarization is released. The coercive electric field of equal to or less than a driving voltage is preferable. The piezoelectric film 15 of the present embodiment satisfies 55 kV/cm≤Ec⁺≤75 kV/cm, and 75 kV/cm≤Ec⁺−Ec⁻≤100 kV/cm, and thus stable and high reliability can be obtained. Further, since the hysteresis curve includes the origin, the polarization reversal does not occur during driving, and power consumption can be suppressed, which leads to long-term reliability.

In a case where the seed layer 13 is provided, since the piezoelectric film 15 having good lattice matching is grown, it is possible to suppress a stress applied to the piezoelectric film 15 as compared to a case where the seed layer 13 is not provided. By suppressing the stress of the piezoelectric film 15, a withstand voltage and durability can be improved, and high reliability can be obtained. In JP2009-71295A, the seed layer 13 is not provided, and the stress is relaxed by including a large amount of crystal grains having a small grain size in the piezoelectric film. However, in a case where the seed layer 13 is provided, the stress can be suppressed without including the crystal grains having a small grain size. The present inventors have found that in a case where the seed layer 13 is provided, the piezoelectric performance and the reliability can be improved by suppressing crystal grains having a small grain size of 100 nm or less. Insulation breakdown often occurs at a grain boundary, and it is considered that the number of grain boundaries can be suppressed by suppressing the number of crystal grains having a small grain size, which leads to improvement of the withstand voltage and the durability.

In a case where the above-described piezoelectric film 15 is formed on the seed layer 13 using a sputtering method, the piezoelectric film 15 is obtained by stopping the film formation once at a stage where an extremely thin film is formed in an initial stage of the film formation, specifically, a film having a film thickness of 100 nm or less is formed, performing an annealing treatment at a high temperature of 600° C. to 700° C., and then performing the film formation to a set film thickness (for example, 2 μm). It is considered that the annealing treatment promotes the crystal growth of the Nb-added PZT and thus the number of crystal grains having a small size can be reduced.

The piezoelectric element 1 or the piezoelectric laminate 5 according to the above embodiment can be applied to an ultrasonic device, a mirror device, a sensor, a memory, and the like.

### EXAMPLES

Hereinafter, specific examples and comparative examples of the piezoelectric element according to the present disclosure will be described. First, a production method for a piezoelectric element of each example will be described. A sputtering device was used for film formation of each layer. The description of the production method will be made with reference to the reference numerals of the respective layers of the piezoelectric element 1 shown in FIG. 1.

### Production Method

A thermal oxide film-attached silicon substrate was used as the substrate 10.

An electrode layer-attached substrate was prepared in which an adhesion layer consisting of Ti and having a thickness of 20 nm, the lower electrode layer 12 consisting of Ir and having a thickness of 150 nm, and the seed layer 13 consisting of SrRuO₃ (SRO in Table 1) and having a thickness of 20 nm were sequentially laminated on a thermal oxide film of the substrate 10. For Comparative Examples 1 and 3, an electrode layer-attached substrate was prepared in which a seed layer was not provided, and the adhesion layer consisting of Ti and having a thickness of 20 nm and the lower electrode layer 12 consisting of Ir and having a thickness of 150 nm were sequentially laminated on the thermal oxide film of the substrate 10.

### Piezoelectric Film

A Nb-added PZT film was formed as the piezoelectric film 15 on the seed layer 13 under the following sputtering conditions. The film formation was once interrupted at the initial stage of the film formation, an annealing treatment was performed, and finally, a Nb-added PZT film having a thickness of 2 μm was formed. For film formation, a Nb-added PZT target was used. A target was used in which a Pb composition ratio=1.3, a Zr/Ti molar ratio is an MPB composition (Zr/Ti=52/48), that is, x=0.52, and a Nb composition ratio y=0.12. A substrate setting temperature during film formation was set to 550° C.

### Sputtering Conditions for Piezoelectric Film

Distance between target and substrate: 100 mm
Target input power: 3 kW
Degree of vacuum (film formation pressure): 0.5 Pa
Atmosphere: Ar/O₂ mixture (O₂ volume fraction: 2.5%)
Set temperature of substrate: 550° C.
Substrate bias voltage: +40 V

### Annealing Conditions

The conditions for temporarily interrupting film formation in the middle of the film formation and performing an annealing treatment were as listed in Table 1. For example, in a case of Example 1, the Nb-added PZT film was formed to a thickness of 30 nm as an initial piezoelectric film, and then the annealing treatment was performed at a temperature of 650° C. for 10 minutes. The annealing treatment was performed in a state in which the film formation was stopped in a film forming apparatus and only the temperature was increased in a vacuum. Further, in Comparative Examples 1 and 2, the piezoelectric film having a thickness of 2 m was formed as it was without stoppage of film formation in the middle of the film formation, that is, without being subjected to the annealing treatment.

### Upper Electrode Layer

An ITO layer having a thickness of 100 nm was formed as the upper electrode layer 18 on the piezoelectric film 15 of the above-described laminated substrate by sputtering.

### Formation of Electrode Pattern for Evaluation

A resist pattern was formed using photolithography before the film formation of the upper electrode layer 18, the upper electrode layer 18 was formed on the resist pattern by film formation, and an upper electrode pattern for evaluation was formed by lifting-off.

The laminates of Comparative Examples and Examples were prepared by the above-described steps. Table 1 collectively shows a seed layer, a piezoelectric film thickness before the annealing treatment (initial piezoelectric film thickness), and a temperature and a time of the annealing treatment in each of Comparative Examples and Examples.

TABLE 1

| | | Initial | Annealing | |
|---|---|---|---|---|
| | | Piezoelectric Film | Treatment | |
| | | Thickness | Temperature | Time |
| | Seed Layer | nm | ° C. | min |
| Comparative | None | 0 | — | — |
| Example 1 | | | | |
| Comparative | SRO 20 nm | 0 | — | — |
| Example 2 | | | | |
| Comparative | None | 30 | 650 | 10 |
| Example 3 | | | | |
| Example 1 | SRO 20 nm | 30 | 650 | 10 |
| Example 2 | SRO 20 nm | 50 | 650 | 10 |
| Example 3 | SRO 20 nm | 100 | 650 | 10 |
| Example 4 | SRO 20 nm | 50 | 700 | 10 |
| Example 5 | SRO 20 nm | 50 | 650 | 30 |

### Preparation of Evaluation Samples

### Evaluation Sample 1

A strip-shaped portion of 2 mm×25 mm was cut out from the laminate to prepare a cantilever as an evaluation sample 1.

### Evaluation Sample 2

A portion of 25 mm×25 mm having, at a center of a surface of the piezoelectric film 15, the upper electrode layer 18 that had been patterned in a circular shape having a diameter of 400 μm was cut out from the laminate and used as an evaluation sample 2.

### Measurement of Polarization-Electric Field Characteristics

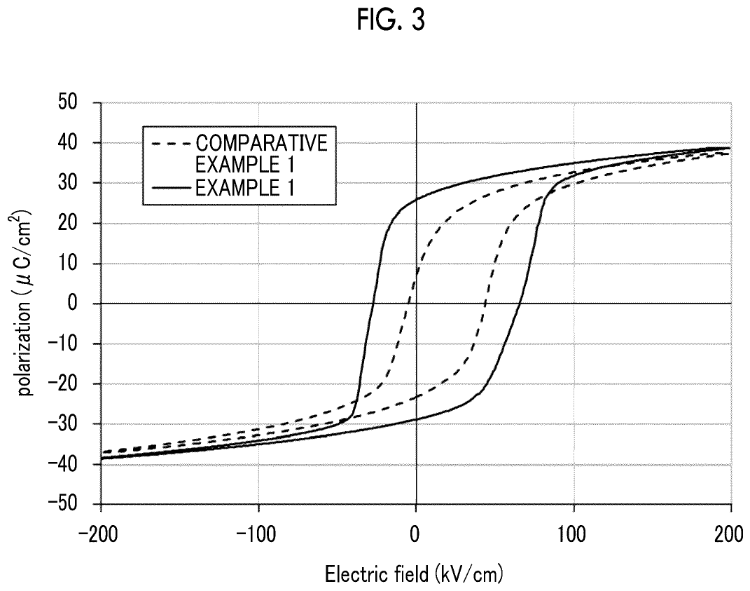

For the piezoelectric element of each of Examples and Comparative Examples, a polarization-electric field (P-E) hysteresis curve was measured using the evaluation sample 2. A ferroelectric characteristic evaluation system FEC10 manufactured by TOYO Corporation was used for the measurement. For the piezoelectric element of each of Examples and Comparative Examples, the lower electrode layer 12 was grounded, the driving voltage applied to the upper electrode layer 18 was changed from 0 V to +40 V to −40 V to 0 V with a triangular wave of 10 Hz, and a change in a polarization value at that time was acquired. The measurement of the hysteresis curve was performed such that the change of the driving voltage from 0 V to +40 V to −40 V to 0 V was set as one cycle and a coercive electric field value was determined from data of a third cycle. As already described, in the measurement of the hysteresis curve, a first cycle is unstable, and, generally, a hysteresis curve that stably exhibits substantially the same behavior is obtained from a second cycle. Here, for the sake of clarity, the data of the third cycle was used. FIG. 3 shows P-E hysteresis curves of Example 1 and Comparative Example 1. A horizontal axis is an electric field calculated by dividing an applied voltage by a thickness of 2 μm.

As shown in FIG. 3, in the hysteresis curve of Example 1, the positive-side coercive electric field Ec⁺ was 66 kV/cm, and the negative-side coercive electric field Ec⁻ was −27 kV/cm. Therefore, |Ec⁺+Ec⁻| was 39 kV/cm, and |Ec⁺−Ec⁻| was 93 kV/cm. The coercive electric field of each of other Examples and Comparative Examples was as shown in Table 2.

### Measurement of Piezoelectric Constant

According to the method described in I. Kanno et al., Sensor and Actuator A 107 (2003) 68, a piezoelectric constant d₃₁ [pm/V] was measured using the cantilever, by using an applied voltage of a sine wave of +10 V±10 V, that is, an applied voltage in which a sine wave having an amplitude of 10 V is added to a bias voltage of +10 V. Before measuring the piezoelectric constant, +40 V was applied for 10 seconds to perform a poling process. The measurement results are shown in Table 2.

The piezoelectric constant was evaluated according to the following standard, and the evaluation results are shown in Table 2 together.
A: 200 pm/V or more
B: 170 pm/V or more and less than 200 pm/V
C: Less than 170 pm/V

### Evaluation of Withstand Voltage

The withstand voltage (dielectric breakdown voltage) of each of Examples and Comparative Examples was measured. Using the evaluation sample 2, the lower electrode layer 12 was grounded, a positive voltage was applied to the upper electrode layer 18 at a change rate of +1 V/sec, and a voltage at which a current of 1 mA or more flowed was regarded as the withstand voltage. Ten samples were prepared for each example, the measurements were carried out a total of 10 times, and an average value thereof is shown in Table 2 as the withstand voltage [V].

The withstand voltage was evaluated according to the following standard, and the evaluation results are shown in Table 2 together.
A: 150 V or more
B: 100 V or more and less than 150 V
C: less than 100 V

### Evaluation of Driving Stability (Reliability)

A time dependent dielectric breakdown (TDDB) test was carried out as an evaluation of driving stability of each of Examples and Comparative Examples. Using the evaluation sample 2, in an environment of 120° C., the lower electrode layer 12 was grounded, a voltage of +40 V was applied to the upper electrode layer 18, and a time (hr) taken from the start of the voltage application to the occurrence of dielectric breakdown was measured. The measurement results are shown in Table 2. The TDDB test was carried out for 2,000 hours, and those in which dielectric breakdown did not occur up to 2,000 hours are described as 2,000 in Table 2.

The reliability was evaluated according to the following standard, and the evaluation results are shown in Table 2 together.
A: 1500 hr or more
B: 1000 hr or more and less than 1500 hr
C: Less than 1000 hr

### Method of Measuring Crystal Grain Size

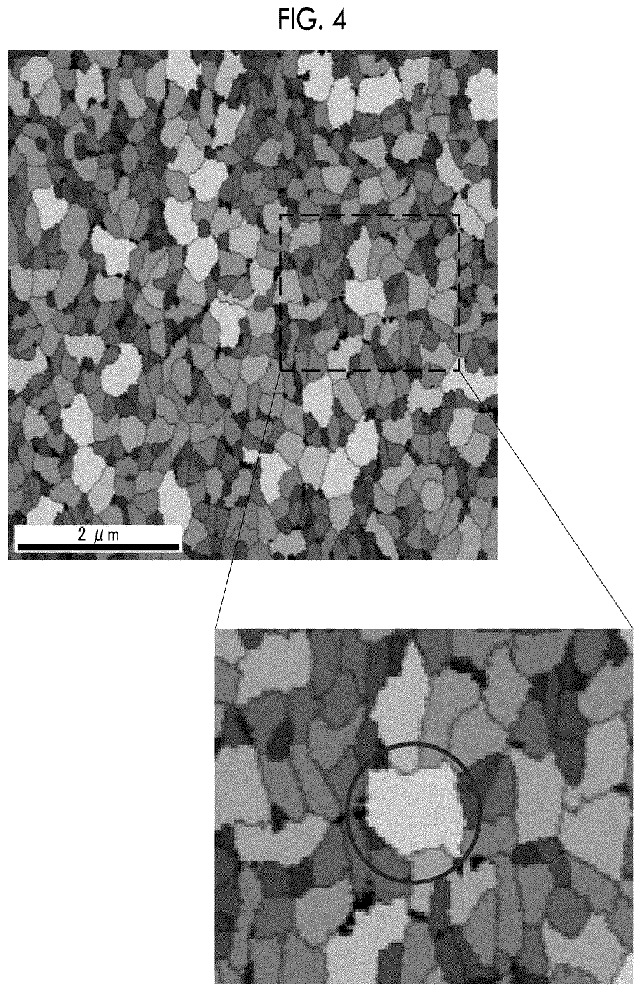

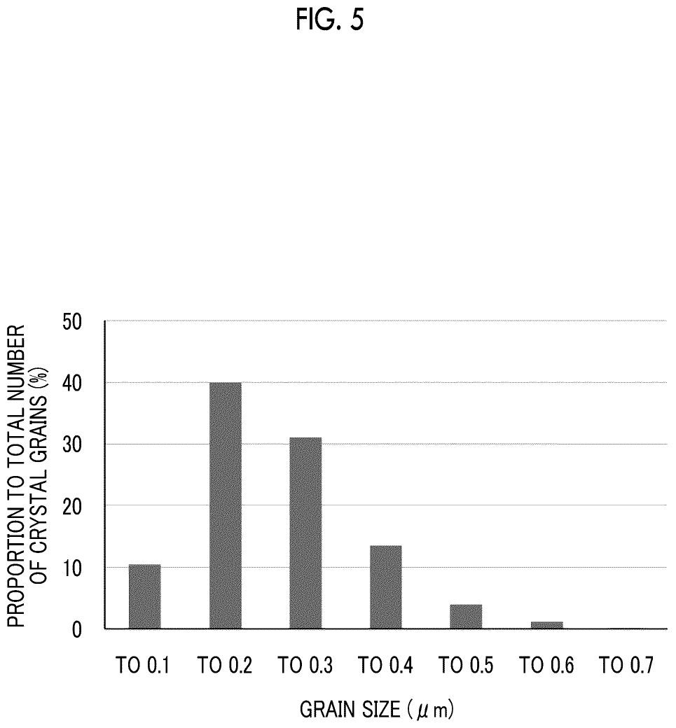

The surface of the piezoelectric film after the film formation, that is, the surface of the piezoelectric film before the film formation of the upper electrode, was measured by EBSD. As a measuring device, a scanning electron microscope (SEM): JSM-7001F manufactured by JEOL Ltd., and EBSD: OIM manufactured by TSL were used. FIG. 4 shows an image pattern of crystal grains on the surface of the piezoelectric film for Example 1 acquired by the EBSD method. As shown in an enlarged view in FIG. 4, the crystal grains were specified, and a diameter of the minimum circumscribed circle was obtained as the crystal grain size. FIG. 5 shows a grain size distribution acquired from FIG. 4. In FIG. 5, in a horizontal axis, ˜0.1 indicates 0.1 μm or less (100 nm or less), ˜0.2 indicates more than 0.1 μm and 0.2 μm or less, and ˜0.3 indicates more than 0.2 μm and 0.3 μm or less. The same applies to ˜0.4 and subsequent values. As shown in FIG. 5, in Example 1, the number of crystal grains having a grain size of 100 nm or less was 10% of the total number of crystal grains in the visual field. The proportions of the crystal grains having a grain size of 100 nm or less in each of Examples and Comparative Examples were as shown in Table 2.

In addition, in Table 2, the lowest evaluation result among the evaluations of the piezoelectric constant, the withstand voltage, and the reliability is shown as an overall evaluation for each of Examples and Comparative Examples.

TABLE 2

| | | | | | Proportion | | | | | | | |
|---|---|---|---|---|---|---|---|---|---|---|---|---|
| | | | | | of Crystal | | | | | | | |
| | | | | | Grains | | | | | | | |
| | | | | | Having | | | | | | | |
| | | | | | Grain Size | Piezoelectric Performance | | | | | | |
| | P-E Hysteresis Curve | | | | of 100 nm | Piezoelectric | | | | | | |
| | Ec⁻ | Ec⁺ | \|Ec⁺ + Ec⁻\| | \|Ec⁺ − Ec⁻\| | or Less | Constant | | Withstand Voltage | | Reliability | | Overall |
| | kV/cm | kV/cm | kV/cm | kV/cm | % | pm/V | Evaluation | V | Evaluation | hr | Evaluation | Evaluation |
| Comparative | −5 | 41 | 36 | 46 | 30 | 200 | A | 50 | C | 500 | C | C |
| Example 1 | | | | | | | | | | | | |
| Comparative | −20 | 55 | 35 | 75 | 35 | 200 | A | 50 | C | 500 | C | C |
| Example 2 | | | | | | | | | | | | |
| Comparative | −12 | 50 | 38 | 62 | 10 | 170 | B | 40 | C | 250 | C | C |
| Example 3 | | | | | | | | | | | | |
| Example 1 | −27 | 66 | 39 | 93 | 10 | 220 | A | 180 | A | 2000 | A | A |
| Example 2 | −24 | 63 | 39 | 87 | 7 | 210 | A | 150 | A | 1500 | A | A |
| Example 3 | −20 | 56 | 36 | 76 | 15 | 200 | A | 100 | B | 1000 | B | B |
| Example 4 | −26 | 73 | 47 | 99 | 3 | 220 | A | 200 | A | 2000 | A | A |
| Example 5 | −26 | 64 | 38 | 90 | 5 | 220 | A | 180 | A | 2000 | A | A |

From the results of Comparative Examples 1 and 3, in a case where there was no seed layer, the piezoelectric constant, the withstand voltage, and the reliability were all higher in Comparative Example 1 where the proportion of crystal grains having a grain size of 100 nm or less was more than 30%.

Examples 1 to 5 were rated B or higher in all evaluations, and good results were obtained in terms of the piezoelectric constant, the withstand voltage, and the reliability. Examples 1 to 5 and Comparative Example 2 satisfied the following expressions. Comparative Examples 1 and 3 did not satisfy at least one of the following expressions:

$$\vert {Ec}^{+} + {Ec}^{-} \vert < \vert {Ec}^{+} - {Ec}^{-} \vert ,$$

$$55 kV / cm \leq {Ec}^{+} \leq 75 kV / cm , and$$

$$75 kV / cm \leq {Ec}^{+} - {Ec}^{-} \leq 100 kV / cm .$$

In Examples 1 to 5, the proportion of crystal grains having a grain size of 100 nm or less was 15% or less. It has become apparent that in a case where the piezoelectric film satisfies the above-described ranges, a good piezoelectric constant, withstand voltage, and reliability are obtained.

In Example 3, the evaluation results of the withstand voltage and the reliability were low as compared to other Examples 1, 2, 4, and 5. From the above results, it is considered that the piezoelectric film 15 in which the proportion of the crystal grains having a grain size of 100 nm or less is 10% or less is more preferable. Further, in a case where the seed layer is provided, in Comparative Example 2 in which the proportion of the crystal grains having a grain size of 100 nm or less was as high as 35%, the piezoelectric constant is good, but the withstand voltage and the reliability are low as compared to Examples 1 to 5. Therefore, the effect of reducing the proportion of the crystal grains having a grain size of 100 nm or less has become apparent.

All documents, patent applications, and technical standards described in the present specification are incorporated in the present specification by reference to the same extent as in a case where each document, patent application, and technical standard are specifically and individually noted to be incorporated by reference.

Furthermore, the following appendices will be disclosed in relation to the above-described embodiment.

### APPENDIX 1

A piezoelectric laminate comprising: a substrate; and a lower electrode layer, a seed layer, and a piezoelectric film provided in this order on the substrate, in which the piezoelectric film contains, as a main component, a first perovskite-type oxide containing Pb, Zr, Ti, and Nb, the seed layer contains, as a main component, a second perovskite-type oxide that is lattice-matched with the first perovskite-type oxide, and in a crystal grain size distribution acquired by an electron back scattered diffraction method, a proportion of crystal grains having a grain size of 100 nm or less is 15% or less in the piezoelectric film, and in a case where a positive-side coercive electric field is defined as Ec⁺ and a negative-side coercive electric field is defined as Ec⁻ in polarization-electric field characteristics, the piezoelectric film satisfies the following expressions: |Ec⁺+Ec⁻|<|Ec⁺−Ec⁻|, 55 kV/cm≤Ec⁺≤75 kV/cm, and 75 kV/cm≤Ec⁺−Ec⁻≤100 kV/cm.

### APPENDIX 2

The piezoelectric laminate according to Appendix 1, in which the piezoelectric film is a sputtered film.

### APPENDIX 3

The piezoelectric laminate according to Appendix 1 or 2, in which the proportion of the crystal grains having a grain size of 100 nm or less is 10% or less.

### APPENDIX 4

The piezoelectric laminate according to any one of Appendices 1 to 3, in which the first perovskite-type oxide is represented by Pbₐ{(ZrₓTi₁₋ₓ)_{1-y}Nb_{y}}O₃, where 0<x<1, 0.08≤y≤0.15, and 0.9≤a≤1.2 are satisfied.

### APPENDIX 5

The piezoelectric laminate according to any one of Appendices 1 to 4, in which the seed layer has conductivity.

### APPENDIX 6

The piezoelectric laminate according to any one of Appendices 1 to 5, in which the second perovskite-type oxide has a lattice constant of 0.39 nm to 0.405 nm in a case of being regarded as a pseudo-cubic crystal.

### APPENDIX 7

The piezoelectric laminate according to any one of Appendices 1 to 6, in which the second perovskite-type oxide is SrRuO₃ or BaRuO₃.

### APPENDIX 8

A piezoelectric element comprising: the piezoelectric laminate according to any one of Appendices 1 to 7; and an upper electrode layer provided on the piezoelectric film of the piezoelectric laminate.

What is claimed is:

1. A piezoelectric laminate comprising:
a substrate; and
a lower electrode layer, a seed layer, and a piezoelectric film provided in this order on the substrate,
wherein the piezoelectric film contains, as a main component, a first perovskite-type oxide containing Pb, Zr, Ti, and Nb, the seed layer contains, as a main component, a second perovskite-type oxide that is lattice-matched with the first perovskite-type oxide, and in a crystal grain size distribution acquired by an electron back scattered diffraction method, a proportion of crystal grains having a grain size of 100 nm or less is 15% or less in the piezoelectric film, and in a case where a positive-side coercive electric field is defined as Ec⁺ and a negative-side coercive electric field is defined as Ec⁻ in polarization-electric field characteristics, the piezoelectric film satisfies the following expressions: |Ec⁺+Ec⁻|<|Ec⁺−Ec⁻|, 55 kV/cm≤Ec⁺≤75 kV/cm, and 75 kV/cm≤Ec⁺−Ec⁻≤100 kV/cm.

2. The piezoelectric laminate according to claim 1,
wherein the piezoelectric film is a sputtered film.

3. The piezoelectric laminate according to claim 1,
wherein the proportion of the crystal grains having a grain size of 100 nm or less is 10% or less.

4. The piezoelectric laminate according to claim 1,
wherein the first perovskite-type oxide is represented by Pbₐ{(ZrₓTi₁₋ₓ)_{1-y}Nb_{y}}O₃,
where 0<x<1, 0.08≤y≤0.15, and 0.9≤a≤1.2 are satisfied.

5. The piezoelectric laminate according to claim 1,
wherein the seed layer has conductivity.

6. The piezoelectric laminate according to claim 1,
wherein the second perovskite-type oxide has a lattice constant of 0.39 nm to 0.405 nm in a case of being regarded as a pseudo-cubic crystal.

7. The piezoelectric laminate according to claim 1,
wherein the second perovskite-type oxide is SrRuO₃ or BaRuO₃.

8. A piezoelectric element comprising:
the piezoelectric laminate according to claim 1; and
an upper electrode layer provided on the piezoelectric film of the piezoelectric laminate.
